(19) United States
(12) Patent Application Publication
(10) Pub. No.: US 2026/0275508 A1
(43) Pub. Date: Sep. 17, 2026

(54) METHOD FOR FORMING METAL NITRIDE THIN FILM

(71) Applicant: WONIK IPS CO., LTD., Pyeongtaek-si Gyeonggi-do (KR)

(72) Inventors: Pil Geun YOON, Pyeongtaek-si Gyeonggi-do (KR); Tae Hak KIM, Pyeongtaek-si Gyeonggi-do (KR); Yeon Gang YOO, Pyeongtaek-si Gyeonggi-do (KR)

(73) Assignee: WONIK IPS CO., LTD., Pyeongtaek-si Gyeonggi-do (KR)

(21) Appl. No.: 18/873,887

(22) PCT Filed: Nov. 2, 2023
(86) PCT No.: PCT/KR2023/017384

§ 371 Date: Dec. 11, 2024

(30) Foreign Application Priority Data
Aug. 21, 2023 (KR) 10-2023-0109147

(51) Int. Cl. C23C 16/34; C23C 16/56; H10P 14/40; H10P 14/43

(52) U.S. Cl. CPC C23C 16/34; C23C 16/56; H10P 14/412; H10P 14/43

(57) ABSTRACT

A method for forming a metal nitride thin film according to embodiments includes steps of: introducing a substrate into a process chamber having a processing space formed therein; forming a metal nitride thin film on the substrate by separately supplying a metal precursor gas and a nitrogen-containing gas; performing first surface treatment at least once on the metal nitride thin film by supplying a hydrogen-containing gas to the process chamber and forming a first plasma; and performing second surface treatment at least once on the first surface-treated metal nitride thin film by supplying a nitrogen-containing gas to the process chamber and forming a second plasma.

### TECHNICAL FIELD

The present disclosure relates to a method for forming a metal nitride thin film.

### BACKGROUND ART

Recently, as semiconductor devices become more miniaturized and highly integrated, there has been an increasing demand for methods that can reduce the number and size of particles and improve film quality. In particular, in the case of metal nitride thin films such as titanium nitride thin films, improving the quality and yield of the thin films has become more important.

In general, the metal nitride thin film is formed using, for example, a chemical vapor deposition (CVD) method in which a metal source gas and a nitrogen-containing gas are supplied into a reaction chamber and thermally reacted to form a thin film on a substrate. Immediately after depositing the metal nitride thin film, metal precursor residues with low flow rate are removed using hydrogen plasma, thereby reducing the level of residues and particles in the film.

However, where a metal nitride thin film having a large thickness is formed using the above-described conventional method, a problem arises in that cracks easily occur in the thin film due to high stress and the formed thin film has high resistance. Therefore, research is needed on a method that can overcome this problem.

### DISCLOSURE

### Technical Problem

Embodiments are intended to provide technical contents relating to a method for forming a metal nitride thin film, which may not only form even a thick metal nitride thin film having low stress and resistance, but also prevent the occurrence of defects such as cracks.

### Technical Solution

A method for forming a metal nitride thin film according to embodiments includes steps of: introducing a substrate into a process chamber having a processing space formed therein; forming a metal nitride thin film on the substrate by separately supplying a metal precursor gas and a nitrogen-containing gas; performing first surface treatment at least once on the metal nitride thin film by supplying a hydrogen-containing gas to the process chamber and forming a first plasma; and performing second surface treatment at least once on the first surface-treated metal nitride thin film by supplying a nitrogen-containing gas to the process chamber and forming a second plasma.

According to one embodiment, the step of forming the metal nitride thin film on the substrate may be performed by reacting the metal precursor gas with the nitrogen-containing gas through thermal chemical vapor deposition (thermal CVD), performed at a temperature of 300 to 800° C., to form the metal nitride thin film.

According to one embodiment, the metal nitride thin film may include any one of titanium nitride (TiN), tungsten nitride (WN), molybdenum nitride (Mo₂N), tantalum nitride (TaN), aluminum nitride (AlN), and titanium aluminum nitride (TiAlN).

According to one embodiment, the metal precursor gas may include at least one metal precursor selected from among titanium tetrachloride (TiCl₄), tetrakis(dimethylamino) titanium (TDMAT, Ti(N(Me₂)₄), tetrakis(diethylamino)titanium (TDEAT, Ti(N(Et₂)₄), and tetrakis(ethylmethylamino)titanium (TEMAT, Ti(N(EtMe)₄).

According to one embodiment, the nitrogen-containing gas may include at least one of ammonia gas (NH₃) and nitrogen gas (N₂).

According to one embodiment, the step of performing first surface treatment and the step of performing second surface treatment may form the first plasma and the second plasma, respectively, by applying dual-frequency power source. In particular, the step of performing first surface treatment and the step of performing second surface treatment may form the first plasma and the second plasma, respectively, by applying at least one of high-frequency power and very high-frequency power together with low-frequency power.

According to one embodiment, the step of performing second surface treatment may be performed by supplying not only the nitrogen-containing gas, but also a hydrogen-containing gas.

### Advantageous Effects

In the method for forming a metal nitride thin film according to embodiments, the metal nitride thin film deposited by thermal chemical vapor deposition is subjected to first surface treatment with hydrogen plasma to remove the metal precursor gas having low flow rate. Through the first surface treatment process, the concentration of residual ions and contaminants in the metal nitride thin film may be lowered and the level of particles in the thin film may be reduced. In addition, the first surface-treated metal nitride thin film is subjected to second surface treatment with a second plasma. Through the second surface treatment process, the stress of the metal nitride thin film may be reduced, the occurrence of cracks in the thin film may be prevented, and the surface resistance of the thin film may be lowered. Accordingly, according to the method for forming a metal nitride thin film according to embodiments, it is possible to form a metal nitride thin film with improved electrical, chemical, and physical properties.

### DESCRIPTION OF DRAWINGS

FIG. 1 is a process diagram showing a method for forming a metal nitride thin film according to embodiments.

FIG. 2 is a timing diagram showing a method for forming a metal nitride thin film according to embodiments.

FIG. 3 is a graph showing ion energy distributions as a function of ion energy at varying frequencies to explain the energy of ions formed by plasma in the method for forming a metal nitride thin film according to embodiments.

FIG. 4 is a graph showing a time-dependent voltage superimposed waveform formed by applying dual-frequency power in the method for forming a metal nitride thin film according to embodiments.

FIG. 5 depicts graphs showing the change in ion energy distribution when applying dual-frequency power in the method for forming a metal nitride thin film according to embodiments.

FIG. 6 is a schematic diagram showing a substrate processing apparatus according to one embodiment.

FIG. 7 shows SIMS data indicating the results of analyzing the chloride ion concentration of a thin film formed by the method according to each of Examples 1 to 3.

FIG. 8 shows electron microscope images of the surfaces of thin films formed by methods according to a Comparative Example (a), Example 1 (b), Example 2 (c), and Example 3 (d).

### MODE FOR INVENTION

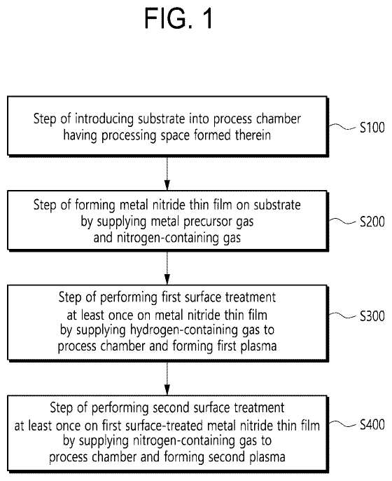

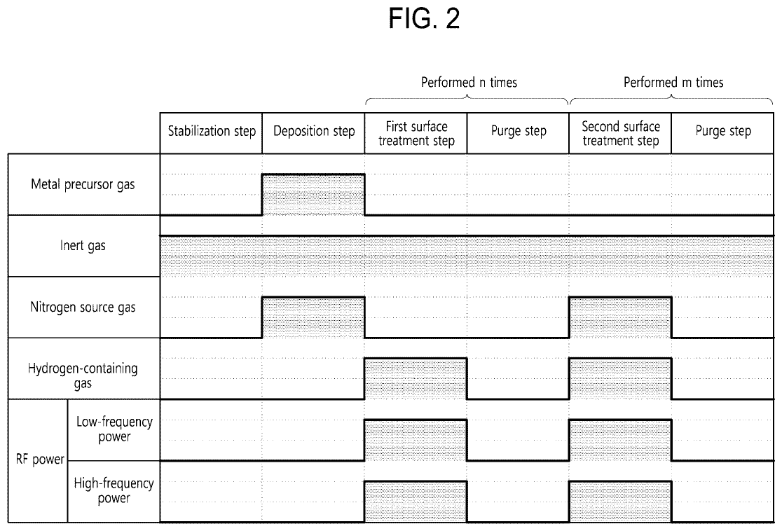

FIG. 1 is a process diagram showing a method for forming a metal nitride thin film according to embodiments. FIG. 2 is a timing diagram showing an example of a method for forming a metal nitride thin film according to embodiments.

Referring to FIGS. 1 and 2, the method for forming a metal nitride thin film according to embodiments includes: step (S100) of introducing a substrate (S) into a process chamber having a processing space formed therein; step (S200) of forming a metal nitride thin film on the substrate (S); step (S300) of performing first surface treatment on the metal nitride thin film; and step (S400) of performing second surface treatment on the first surface-treated metal nitride thin film. The method for forming a metal nitride thin film according to embodiments may be performed using any type of conventional substrate processing apparatus that is utilized to form a metal nitride thin film on a substrate (S). In addition, the substrate processing apparatus may be utilized to perform a plasma-enhanced chemical vapor deposition process.

First, in step (S100) of introducing the substrate, the substrate (S) is mounted on a substrate mounting unit 130 installed in the processing space of the process chamber.

The substrate (S) may be any type of conventional substrate that is used to manufacture a semiconductor device by forming a metal nitride thin film thereon.

Next, in step (S200) of forming the metal nitride thin film, the metal nitride thin film is formed on the substrate (S) by separately supplying a metal precursor gas and a nitrogen-containing gas onto the substrate (S).

In this step, the metal nitride thin film may be formed by separately supplying the metal precursor gas and the nitrogen-containing gas and reacting the metal precursor gas with the nitrogen-containing gas. In this step, the metal nitride thin film may be formed by thermal chemical vapor deposition. The thermal chemical vapor deposition may be performed at a temperature of 300 to 800° C. In particular, the thermal chemical vapor deposition may be performed at a temperature of 500 to 700° C.

The metal nitride thin film may include at least one of titanium nitride (TiN), tungsten nitride (WN), molybdenum nitride (Mo₂N), tantalum nitride (TaN), aluminum nitride (AlN), and titanium aluminum nitride (TiAlN).

As the metal precursor gas, any conventional metal precursor gas that is used to form a metal nitride thin film may be supplied.

In particular, the metal nitride thin film may be a titanium nitride thin film. Accordingly, the metal precursor gas may include a metal precursor including at least one of titanium tetrachloride (TiCl₄), tetrakis(dimethylamino)titanium (TDMAT, Ti(N(Me₂)₄), tetrakis(diethylamino) titanium (TDEAT, Ti(N(Et₂)₄), and tetrakis(ethylmethylamino)titanium (TEMAT, Ti(N(EtMe)₄).

The nitrogen-containing gas may include at least one of ammonia gas (NH₃) and nitrogen gas (N₂).

When a metal nitride thin film is formed using the thermal chemical vapor deposition, a problem arises in that cracks easily occur in the metal nitride thin film due to high stress and the formed thin film has high resistance. In the method for forming a metal nitride thin film according to embodiments, a metal nitride thin film with excellent properties may be formed by introducing a PECVD process to surface-treat the metal nitride thin film with each of a first plasma and a second plasma.

Next, in the first surface treatment step (S300), first surface treatment may be performed on the metal nitride thin film by supplying a hydrogen-containing gas to the process chamber 110 and forming a first plasma.

In this step, first surface treatment is performed on the metal nitride thin film by supplying a hydrogen-containing gas and forming a first plasma. Through the first surface treatment, it is possible to remove residual metal precursor gases having low flow rate, thereby lowering the concentrations of residual ions and contaminants in the metal nitride thin film and reducing the level of particles. The hydrogen-containing gas may be hydrogen (H₂) gas.

In this step, in order to perform the first surface treatment on the metal nitride thin film, the first plasma may be formed by applying at least one of low-frequency power (LF), high-frequency power (HF), and very high-frequency power (VHF).

According to one embodiment, in this step, the first plasma may be formed by applying dual-frequency power. The first plasma may be formed by applying high-frequency (HF) power and low-frequency (LF) power. Alternatively, the first plasma may be formed by applying very high-frequency (VHF) power and low-frequency (LF) power. In addition, the first plasma may also be formed by applying very high frequency (VHF) power and high frequency (HF) power. In particular, the first plasma may be formed by applying either very high frequency (VHF) power or high frequency (HF) power and low frequency (LF) power.

According to one embodiment, in this step, hydrogen (H₂) gas is supplied onto the metal nitride thin film. In addition, the first plasma is formed by simultaneously applying a low frequency (LF) power of 460 kHz or less and a high frequency (HF) power of 13.56 MHz. Then, first surface treatment may be performed on the metal nitride thin film using the first plasma for 0.01 to 60 seconds.

In addition, in this step, the first surface treatment may be performed n times (wherein n means a natural number greater than or equal to 1). Specifically, the process of performing the first surface treatment on the metal nitride thin film for a predetermined period of time by supplying the hydrogen-containing gas to the process chamber and forming the first plasma may be performed at least once. When the first surface treatment is performed repeatedly, residual metal precursor gases, residual ions in the film, contaminants and particles may be removed more efficiently from the film.

Next, in the second surface treatment step (S400), second surface treatment is performed on the first surface-treated metal nitride thin film. Through the second surface treatment, the surface of the metal nitride thin film may be nitrided by supplying a nitrogen-containing gas to the process chamber 110 and forming a second plasma. The second surface treatment reduces the stress and surface resistance of the metal nitride thin film. In addition, the second surface treatment prevents cracks from occurring in the metal nitride thin film.

Specifically, in this step, a nitrogen-containing gas, which is a reactive gas, is supplied onto the first surface-treated metal nitride thin film, and a second plasma is formed. In particular, in this step, hydrogen gas may be supplied together with the nitrogen-containing gas, thereby further enhancing the effect of the second surface treatment.

More specifically, the nitrogen-containing gas is ionized by the second plasma to form nitrogen ions. The first surface-treated metal nitride thin film is exposed to the second plasma, so that the metal precursor on the surface, impurities contained in the metal precursor, and hydrogen contained in the reactive gas are ionized. The metal precursor ions and the nitrogen ions combine to form an ionic compound on the metal nitride thin film. The above ionic compound forms a part of the metal nitride thin film. In addition, the ionized residual impurities and ionized hydrogen combine and are removed from the surface of the metal nitride thin film. Accordingly, the second plasma treatment may reduce the stress of the metal nitride thin film, prevent cracks from occurring in the metal nitride thin film, and lower the surface resistance of the metal nitride thin film.

In addition, in this step, the second surface treatment may be performed by continuously supplying argon gas together with the reactive gas.

In addition, in this step, the metal nitride thin film may be nitrided by forming the second plasma by applying at least one of low-frequency power, high-frequency power, and very high-frequency power.

According to one embodiment, in this step, the second plasma may be formed by applying dual-frequency power.

Specifically, the second plasma may be formed by applying high-frequency (HF) power and low-frequency (LF) power. Alternatively, the second plasma may be formed by applying very high-frequency (VHF) power and low-frequency (LF) power.

In particular, in this step, the second plasma may be formed by applying high-frequency (HF) power and low-frequency (LF) power. This is because the properties of the film can be further improved when considering the plasma energy and density, which are the characteristics of each of the high-frequency (HF) power and the low-frequency (LF) power.

According to one embodiment, in this step, second surface treatment may be performed on the metal nitride thin film for 0.01 to 60 seconds by supplying a nitrogen-containing gas onto the metal nitride thin film and simultaneously applying a low-frequency power of 460 kHz or less and a high-frequency power of 13.56 MHz.

In addition, in this step, second surface treatment may be performed m times on the first surface-treated metal nitride thin film by supplying a nitrogen-containing gas and forming a second plasma (wherein m means a natural number greater than or equal to 1). By repeatedly performing the second surface treatment step (S400) as described above, it is possible to further improve the stress reduction efficiency, thereby further reducing film cracks and surface resistance.

In the above-described method for forming a metal nitride thin film according to embodiments, the properties of the metal nitride thin film may be further improved by forming each of the first plasma and the second plasma using dual-frequency power.

Specifically, one of the factors that play a direct role in performing the thin film deposition and surface treatment processes using each of the first plasma and the second plasma is ions. The ions affect the electrical, chemical, and physical properties of the thin film to be deposited depending on the ion energy characteristics.

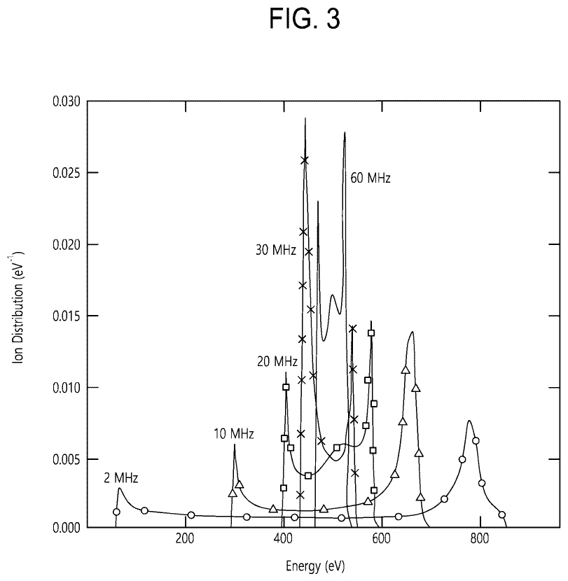

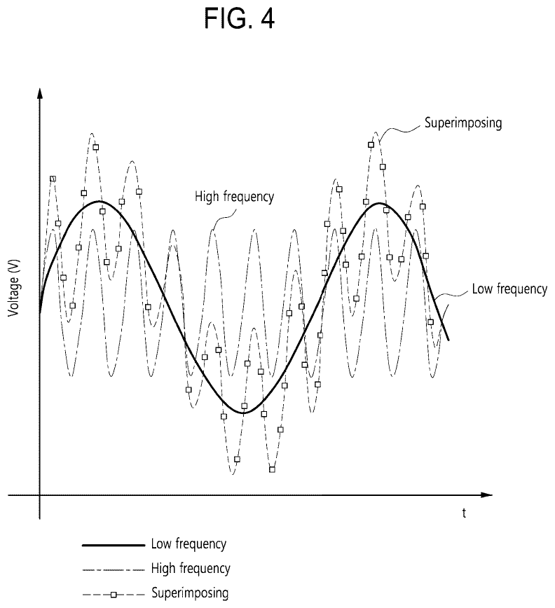

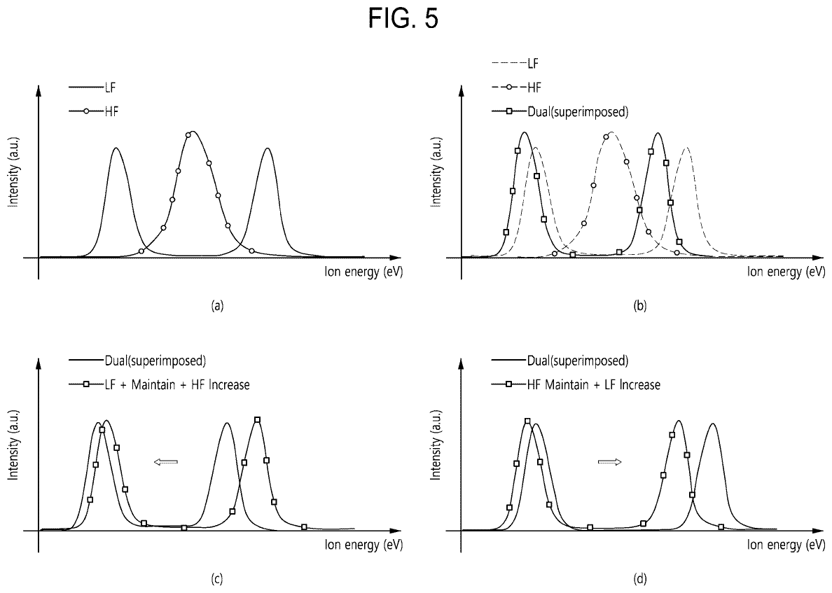

FIG. 3 is a graph showing ion energy distributions as a function of ion energy intensity (unit: eV) at varying frequencies to explain the ion energy formed by plasma in the method for forming a metal nitride thin film according to embodiments. FIG. 4 is a graph showing a time-dependent voltage superimposed waveform formed by applying dual frequency power in the method for forming a metal nitride thin film according to embodiments. FIG. 5 depicts graphs showing the change in ion energy distribution when applying dual frequency power in the method for forming a metal nitride thin film according to embodiments.

In general, when plasma is formed using single-frequency power, the ion energy distribution exhibits a monomodal or bimodal peak. At this time, the ion energy distribution exhibits different modal peaks depending on differences in the ion transit time and the operating frequency. In addition, the sheath electrodes also change simultaneously depending on the operating frequency of the power source for plasma formation.

In particular, capacitively coupled plasma (CCP) cannot control ion energy while maintaining constant density characteristics. The capacitively coupled plasma can control plasma density and ion energy using powers of different frequencies.

Typically, low-frequency power produces high ion energy at low density. High-frequency power produces low ion energy at high density. A single-electrode type to which two different frequencies are applied is called a superimposed electrode, and powers of two frequencies are superimposed and exhibit a superimposed frequency (see FIG. 4).

Referring to FIG. 5, when dual plasma is formed using powers of different frequencies, as the high frequency is applied to the low frequency plasma, the plasma density increases, the thickness of the plasma sheath decreases, and thus the ion energy distribution shifts toward the lower side (see FIGS. 5(a) and 5(b)).

In addition, when the high-frequency power in dual frequencies increases, the ion energy distribution shifts toward low energy. Conversely, when the low-frequency power in dual frequencies increases, the ion energy distribution shifts toward higher energy.

Accordingly, the dual-frequency power is converted into a superposed state using two different frequencies. The dual-frequency power can form an appropriate ion energy and induce a deposition reaction with the density appropriately controlled, compared to when a single frequency is used. In addition, the characteristics of different frequency bands can all be applied as a method for controlling the power. When the dual frequency power is used, the effect of removing metal precursor gases, reducing the concentrations of residual ions and contaminants in the film, and removing particles may be improved compared to when the first plasma is formed using single-frequency power. In addition, when the dual-frequency power is utilized, the nitriding effect may be improved compared to when the second plasma is formed using single-frequency power, thereby further reducing the stress of the film and more effectively preventing crack occurrence, thus improving the properties of the thin film.

In the above-described method for forming a metal nitride thin film according to embodiments, the metal nitride thin film deposited by thermal chemical vapor deposition may be subjected to first surface treatment with hydrogen plasma to remove metal precursor gases having low flow rate. Accordingly, the concentrations of residual ions and contaminants in the metal nitride thin film may be lowered and the level of particles can be reduced. In addition, by nitriding the first surface-treated metal nitride thin film using the second plasma, the stress of the thin film may be reduced, crack occurrence in the thin film may be prevented, and the surface resistance of the thin film may be lowered. Accordingly, a metal nitride thin film having improved electrical, chemical, and physical properties may be formed.

Meanwhile, in the method for forming a metal nitride film according to embodiments, a metal nitride thin film may be formed using a substrate processing apparatus with any conventional structure that is used for performing plasma-enhanced chemical vapor deposition. For example, in the method for forming a metal nitride film according to embodiments, a metal nitride thin film may be formed on a substrate using the following substrate processing apparatus.

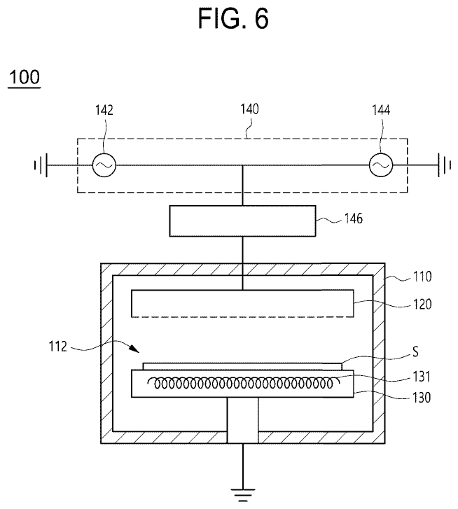

FIG. 6 is a schematic diagram showing a substrate processing apparatus according to one embodiment.

Referring to FIG. 6, a substrate processing apparatus 100 according to one embodiment may have a structure including, as basic components, a process chamber 110, a gas injection unit 120, a substrate mounting unit 130, and a plasma power supply unit 140.

The process chamber 110 may have a processing space 112 defined therein. For example, the process chamber 110 is configured to maintain airtightness, and may be connected to a vacuum chamber (not shown) through an exhaust port to discharge process gas from the processing space 112 and control the vacuum level within the processing space 112. The process chamber 110 may have various shapes. For example, the process chamber 110 may have a structure including a side wall portion defining the processing space 112 and a cover portion positioned on the upper end of the side wall portion.

The gas injection unit 120 may be installed in the process chamber 110 to supply process gas from the outside of the process chamber 110 to the processing space 112. The gas injection unit 120 may be installed in the upper portion of the process chamber 110 to face the substrate mounting unit 13 so as to inject process gas onto a substrate (S) mounted on the substrate mounting unit 130. The gas injection unit 120 may include at least one inlet hole formed through the upper portion or side portion thereof to receive process gas from the outside, and a plurality of downward injection holes formed to face the substrate (S) and configured to inject process gas onto the substrate (S). For example, the gas injection unit 120 may have various shapes, such as a shower head shape, a nozzle shape, etc. When the gas injection unit 120 has a shower head shape, the gas injection unit 120 may be coupled to the process chamber 110 in a shape that covers the upper portion of the process chamber 110. For example, the gas injection unit 120 may be coupled to the side wall of the process chamber 110 to form a cover for the process chamber 110.

The substrate mounting portion 130 is installed in the process chamber 110 to face the gas injection portion 120, and a substrate (S) may be mounted thereon. The substrate mounting portion 130 may have a structure corresponding to the shape of the substrate. The substrate mounting portion 130 may include a heater 131 for heating the substrate (S). In addition, the substrate mounting portion 130 may include a heater power supply for supplying power to the heater 131. Accordingly, the substrate mounting portion 130 may heat the substrate by supplying power to the heater 131. The substrate mounting portion (130) may be connected to an external motor to form a vertically movable structure, and may also be called a substrate support, a substrate susceptor, etc.

The plasma power supply unit 140 may include at least one RF power source configured to apply at least one RF (radio frequency) power to the process chamber 110 to form a plasma atmosphere in the process chamber 110. For example, the plasma power supply unit 140 may be connected to the gas injection unit 120 to apply RF power to the gas injection unit 120. In this case, the gas injection unit 120 may also be called a power supply electrode or an upper electrode. An impedance matching unit 146 may be disposed between the plasma power supply unit 140 and the gas injection unit 120 to match the impedance between the RF power source and the process chamber 110.

The plasma power supply unit 140 may include one or more RF power sources. For example, the plasma power supply unit may include a plurality of RF power sources with different frequency bands to control the plasma environment depending on process conditions. The dual-frequency power source consisting of the first RF power source 142 and the second RF power source 144 has the advantage of being able to precisely control the process because the frequency band may be varied depending on process conditions or process steps. Although the figure shows two RF power sources 142 and 144 as the power source of the plasma power supply unit 140, this is exemplary and the scope of the present disclosure is not limited thereto.

Specifically, the plasma power supply unit 140 may include at least one of low-frequency (LF) power in a frequency range of 100 kHz to 5 MHz, high-frequency (HF) power in a frequency range of 5 to 30 MHz, and very high-frequency (VHF) power in a frequency range of 30 to 80 MHz, and thus apply each of low-frequency RF power, high-frequency RF power, and very high-frequency RF power.

In addition, the substrate processing apparatus according to the embodiment may further include a filter, a current control circuit, etc. for impedance adjustment, current control, etc., without being limited thereto.

Hereinafter, the present disclosure will be described in more detail by way of examples.

The following examples are only specific examples of the present disclosure and are not intended to limit the technical scope of the present disclosure.

### Example 1

A substrate was placed inside a processing space of a process chamber. Then, titanium tetrachloride gas and ammonia gas were separately supplied into the processing space. In addition, a titanium nitride thin film was formed on the substrate by a thermal CVD process at a temperature of 650° C. Thereafter, a purge step was performed to remove unreacted gases.

Next, hydrogen (H₂) gas was supplied onto the titanium nitride thin film. In addition, a first plasma was formed by applying a low-frequency power of 450 kHz at a power of 450 W. The titanium nitride thin film was surface-treated for 10 seconds with hydrogen plasma containing hydrogen ions formed by the first plasma.

Next, ammonia (NH₃) gas and hydrogen (H₂) gas were separately supplied onto the first surface-treated titanium nitride thin film. In addition, a second plasma was formed by applying a low-frequency power of 450 kHz at a power of 450 W. The titanium nitride thin film was nitrided for 30 seconds using nitrogen plasma containing nitrogen ions formed by the second plasma. Accordingly, a titanium nitride thin film having a thickness of 802 Å was formed on the substrate. Here, the hydrogen plasma treatment and the second plasma treatment were each performed once.

### Example 2

A titanium nitride thin film was surface-treated using a first plasma formed by applying a high-frequency power of 13.56 MHz at a power of 450 W. Next, the titanium nitride thin film surface-treated with hydrogen plasma was nitrided using a second plasma formed by applying a high-frequency power of 13.56 MHz at a power of 450 W. Except for these, a titanium nitride thin film was formed in the same manner as in Example 1. Accordingly, the formed titanium nitride thin film was confirmed to have a thickness of 788 Å.

### Example 3

A titanium nitride thin film was formed in the same manner as in Example 1, except that surface treatments were performed using a first plasma and second plasma formed by applying a low-frequency power of 450 kHz and a high-frequency power of 13.56 MHz, respectively, at a power of 450 W. Accordingly, the formed titanium nitride thin film was confirmed to have a thickness of 793 Å.

### Comparative Example

A titanium nitride thin film was formed on a substrate by a thermal CVD process by separately supplying titanium tetrachloride gas and ammonia gas, in the same manner as in Example 1, except that surface treatments with the first plasma and the second plasma were not performed. Accordingly, the formed titanium nitride thin film was confirmed to have a thickness of 796 Å.

### Experimental Example

### (1) Evaluation of Effect of Hydrogen Plasma Treatment

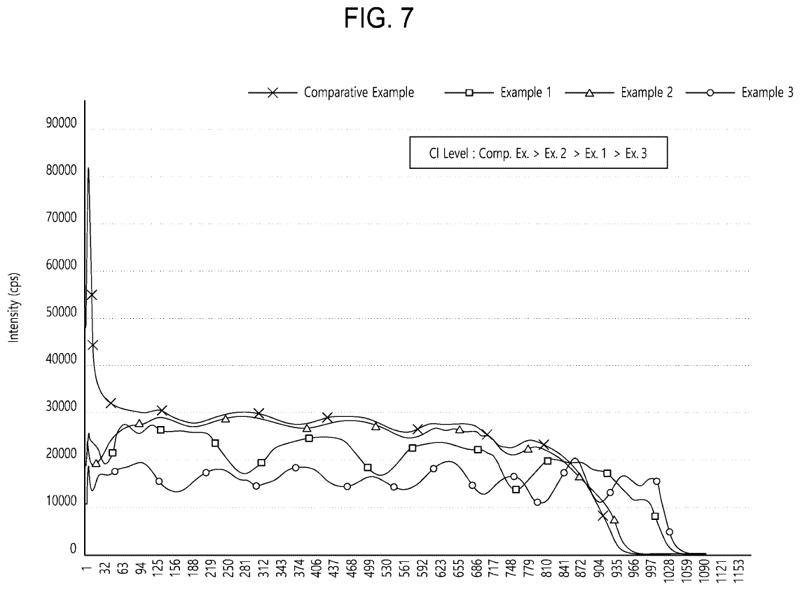

To evaluate the effect of hydrogen plasma treatment, the chloride ion concentration of each of the thin films formed by the methods according to Examples 1 to 3 was analyzed by secondary ion mass spectrometry (SIMS), and the results are shown in FIG. 7. At this time, a thin film that was not treated with hydrogen plasma was also evaluated as an untreated control.

As shown in FIG. 7, it could be confirmed that the concentration of chlorine ions was reduced by hydrogen plasma treatment, and in particular, it could be confirmed that the use of dual plasma was most effective in removing residual chlorine ions.

### (2) Evaluation 1 of Effect of Surface Nitriding

In order to evaluate the effect of surface nitriding on resistance, the thickness (unit: Å), stress (unit: MPa), average sheet resistance (Rs avg., unit: Ω/□), and sheet resistance uniformity (Rs Unif., unit: %) of each of the thin films formed by the methods according to the Examples and the Comparative Example were evaluated, and the results are shown in Table 1 below.

TABLE 1

| | | | Plasma | | Rs | |
|---|---|---|---|---|---|---|
| Surface | Thick- | | power | Stress | Rs avg. | Rs Unif. |
| nitriding | ness | Gas | (W) | (MPa) | (Ω/□) | (%) |
| Thermal | 796 | NH₃ | X | 2247.1 | 102.5 | 2.9 |
| (Comparative | | and | | | | |
| Example) | | H₂ | | | | |
| 450 kHz | 802 | | 450 | 1518.8 | 73.0 | 3.6 |
| (Example 1) | | | | | | |
| 13.56 MHz | 788 | | 450 | 1406.7 | 74.2 | 2.2 |
| (Example 2) | | | | | | |
| Dual | 793 | | 450 | 1163.5 | 70.2 | 1.8 |
| (Example 3) | | | | | | |

As shown in Table 1 above, it could be confirmed that when each of the methods according to the Examples and the Comparative Example was used in the process of forming a titanium nitride thin film with a target thickness of 800 Å, thin films without significant deviation were formed.

In addition, it could be confirmed that the stress of the thin film subjected to surface nitriding was reduced by 32% or more compared to that of the Comparative Example as the untreated control, and in particular, it was confirmed that the stress of the thin film was reduced by 48% or more when treated with dual plasma.

In addition, as a result of evaluating the average sheet resistance and sheet resistance uniformity of each thin film, it could be confirmed that the resistance characteristics were significantly improved by the dual-frequency plasma treatment, and that the physical properties could be improved even when HF power was applied.

### (3) Evaluation 2 of Effect of Surface Nitriding

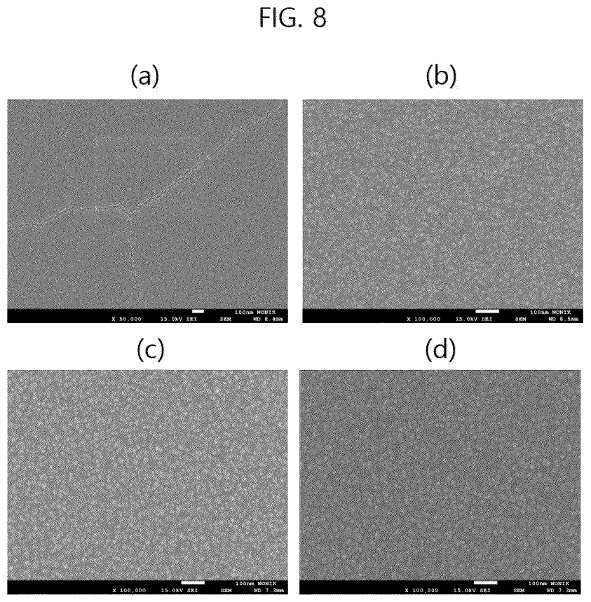

In order to evaluate the effect of plasma nitriding on the formation of cracks in thin films, the quality of the thin films formed by the methods according to the Examples and the Comparative Example was evaluated using an electron microscope, and the results are shown in FIG. 8.

As shown in FIGS. 8(b), 8(c) and 8(d), cracks did not occur in any of the thin films treated with plasma. However, as shown in FIG. 8(a), it could be confirmed that cracks occurred only in the Comparative Example that was not treated with plasma. From these results, it could be confirmed that plasma nitriding treatment could prevent cracks from occurring in the thin film.

From the above results, it can be seen that, when the method for forming a metal nitride thin film according to embodiments is used, cracks do not easily occur even when a metal nitride thin film having a large thickness is formed, and a metal nitride thin film having excellent electrical properties due to its low resistance and low residue concentration may be formed.

### DESCRIPTION OF REFERENCE NUMERALS

100: Substrate processing apparatus
110: Process chamber
120: Gas injection unit
130: Substrate mounting unit
140: Plasma power supply unit
S: Substrate

1. A method for forming a metal nitride thin film, comprising steps of:
introducing a substrate into a process chamber having a processing space formed therein;
forming a metal nitride thin film on the substrate by separately supplying a metal precursor gas and a nitrogen-containing gas;
performing first surface treatment at least once on the metal nitride thin film by supplying a hydrogen-containing gas to the process chamber and forming a first plasma; and
performing second surface treatment at least once on the first surface-treated metal nitride thin film by supplying a nitrogen-containing gas to the process chamber and forming a second plasma.

2. The method of claim 1, wherein the step of forming the metal nitride thin film is performed by reacting the metal precursor gas with the nitrogen-containing gas through thermal chemical vapor deposition (thermal CVD), performed at a temperature of 300 to 800° C., to form the metal nitride thin film.

3. The method of claim 1, wherein the metal nitride thin film comprises any one of titanium nitride (TiN), tungsten nitride (WN), molybdenum nitride (Mo₂N), tantalum nitride (TaN), aluminum nitride (AlN), and titanium aluminum nitride (TiAlN).

4. The method of claim 1, wherein the metal precursor gas comprises at least one metal precursor selected from among titanium tetrachloride (TiCl₄), tetrakis(dimethylamino) titanium (TDMAT, Ti(N(Me₂)₄), tetrakis(diethylamino)titanium (TDEAT, Ti(N(Et₂)), and tetrakis(ethylmethylamino)titanium (TEMAT, Ti(N(EtMe)₄).

5. The method of claim 1, wherein the nitrogen-containing gas comprises at least one of ammonia gas (NH₃) and nitrogen gas (N₂).

6. The method of claim 1, wherein the step of performing first surface treatment comprises forming the first plasma by applying dual-frequency power.

7. The method of claim 6, wherein the first plasma is formed by applying at least one of high-frequency power and very high-frequency power together with low-frequency power.

8. The method of claim 1, wherein the step of performing second surface treatment comprises forming the second plasma by applying dual-frequency power.

9. The method of claim 8, wherein the second plasma is formed by applying at least one of high-frequency power and very high-frequency power together with low-frequency power.

10. The method of claim 1, wherein the step of performing second surface treatment comprises further supplying a hydrogen-containing gas.
